(19) United States
(12) Patent Application Publication
(10) Pub. No.: US 2025/0353136 A1
(43) Pub. Date: Nov. 20, 2025

(54) Polishing Pad Assembly for Electrochemical Mechanical Polishing

(71) Applicant: Wolfspeed, Inc., Durham, NC (US)

(72) Inventor: Simon Bubel, Carrboro, NC (US)

(21) Appl. No.: 18/663,883

(22) Filed: May 14, 2024

(51) Int. Cl. B24B 37/24; C25F 3/30; H01L 21/02

(52) U.S. Cl. CPC B24B 37/24; C25F 3/30; H01L 21/02005

(57) ABSTRACT

An example polishing system, such as an electrochemical mechanical polishing (ECMP) system, includes a polishing pad assembly having a polishing pad. The example polishing system includes a bias source. The example polishing system includes a workpiece carrier operable to bring the semiconductor workpiece into contact with the polishing pad. In some implementations, the polishing pad assembly is operable to provide an electrically conductive path for one or more charge carriers to the bias source.

### FIELD

The present disclosure relates generally to semiconductor workpieces and semiconductor workpiece fabrication, and more particularly to polishing systems and methods for semiconductor workpieces, such as silicon carbide semiconductor wafers.

### BACKGROUND

Power semiconductor devices are used to carry large currents and support high voltages. A wide variety of power semiconductor devices are known in the art including, for example, transistors, diodes, thyristors, power modules, discrete power semiconductor packages, and other devices. For instance, example semiconductor devices may be transistor devices such as Metal Oxide Semiconductor Field Effect Transistors (“MOSFET”), bipolar junction transistors (“BJTs”), Insulated Gate Bipolar Transistors (“IGBT”), Gate Turn-Off Transistors (“GTO”), junction field effect transistors (“JFET”), high electron mobility transistors (“HEMT”) and other devices. Example semiconductor devices may be diodes, such as Schottky diodes or other devices.

Power semiconductor devices may be packaged into various semiconductor device packages, such as discrete semiconductor device packages and power modules. Power modules may include one or more power devices and other circuit components and can be used, for instance, to dynamically switch large amounts of power through various components, such as motors, inverters, generators, and the like.

Semiconductor devices may be fabricated from wide bandgap semiconductor materials, such as silicon carbide and/or Group III nitride-based semiconductor materials. The fabrication process for power semiconductor devices may require processing of wide bandgap semiconductor wafers, such as silicon carbide semiconductor wafers.

### SUMMARY

Aspects and advantages of embodiments of the present disclosure will be set forth in part in the following description, or may be learned from the description, or may be learned through practice of the embodiments.

In an aspect, the present disclosure provides an example polishing system. In some implementations, the example polishing system includes a polishing pad assembly comprising a polishing pad. In some implementations, the example polishing system includes a bias source. In some implementations, the example polishing system includes a workpiece carrier operable to bring the semiconductor workpiece into contact with the polishing pad. In some implementations, the polishing pad assembly is operable to provide an electrically conductive path for one or more charge carriers to the bias source.

In an aspect, the present disclosure provides an example polishing pad. In some implementations, the example polishing pad includes a composite material. In some implementations, the example polishing pad includes one or more conductive structures to provide an electrically conductive path through the polishing pad.

In an aspect, the present disclosure provides an example method. In some implementations, the example method includes providing the surface of the workpiece on a polishing pad assembly. In some implementations, the example method includes providing an electrolyte onto a surface of the polishing pad assembly. In some implementations, the example method includes providing a bias between the workpiece and the electrolyte through an electrically conductive path at least partially through the polishing pad assembly.

These and other features, aspects and advantages of various embodiments will become better understood with reference to the following description and appended claims. The accompanying drawings, which are incorporated in and constitute a part of this specification, illustrate embodiments of the present disclosure and, together with the description, explain the related principles.

### BRIEF DESCRIPTION OF THE DRAWINGS

Detailed discussion of embodiments directed to one of ordinary skill in the art are set forth in the specification, which refers to the appended figures, in which:

FIG. 1 depicts an example polishing system for a semiconductor workpiece according to example embodiments of the present disclosure;

FIGS. 2A and 2B depict a cross-sectional view of an example polishing pad according to example aspects of the present disclosure;

FIG. 3 depicts a top-down view of an example polishing pad according to example aspects of the present disclosure;

FIG. 4 depicts a top-down view of an example polishing pad according to example aspects of the present disclosure;

FIG. 5 depicts a top-down view of an example polishing pad according to example aspects of the present disclosure;

FIGS. 6A, 6B, 6C, and 6D each depict a top-down view of an example polishing pad according to example aspects of the present disclosure;

FIG. 7 depicts a cross-sectional view of a polishing pad, platen, and intermediate layers therebetween according to example aspects of the present disclosure;

FIG. 8 depicts a cross-sectional view of a polishing pad, platen, and intermediate layers therebetween according to example aspects of the present disclosure;

FIG. 9 depicts a cross-sectional view of a polishing pad, platen, and intermediate layers therebetween according to example aspects of the present disclosure;

FIG. 10 depicts a cross-sectional view of a polishing pad, platen, and intermediate layers therebetween according to example aspects of the present disclosure; and

FIG. 11 depicts a flow chart of an example method according to example embodiments of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations can be made to the embodiments without departing from the scope or spirit of the present disclosure. For instance, features illustrated or described as part of one embodiment can be used with another embodiment to yield a still further embodiment. Thus, it is intended that aspects of the present disclosure cover such modifications and variations.

Power semiconductor devices are often fabricated from wide bandgap semiconductor materials, such as silicon carbide or Group III-nitride based semiconductor materials (e.g., gallium nitride). Herein, a wide bandgap semiconductor material refers to a semiconductor material having a bandgap greater than 1.40 eV. Aspects of the present disclosure are discussed with reference to silicon carbide-based semiconductor structures as wide bandgap semiconductor structures. Those of ordinary skill in the art, using the disclosures provided herein, will understand that example embodiments of the present disclosure may be used with any semiconductor material, such as other wide bandgap semiconductor materials, without deviating from the scope of the present disclosure. Example wide bandgap semiconductor materials include silicon carbide and the Group III-nitrides.

Power semiconductor devices may be fabricated using epitaxial layers formed on a semiconductor workpiece, such as a silicon carbide semiconductor wafer. Power semiconductor device fabrication processes may include surface processing operations that are performed on the silicon carbide semiconductor wafer to prepare one or more surfaces of the silicon carbide semiconductor wafer for later processing steps, such as surface implantation, formation of epitaxial layers, metallization, etc. Example surface processing operations may include grinding operations, lapping operations, and polishing operations.

Aspects of the present disclosure are discussed with reference to a semiconductor workpiece that is a semiconductor wafer that includes silicon carbide (“silicon carbide semiconductor wafer”) for purposes of illustration and discussion. Those of ordinary skill in the art, using the disclosures provided herein, will understand that aspects of the present disclosure can be used with other semiconductor workpieces. Other semiconductor workpieces may include carrier substrates, ingots, boules, polycrystalline substrates, monocrystalline substrates, bulk crystalline material having a thickness of greater than about 1 mm, such as greater than about 5 mm, such as greater than about 10 mm, such as greater than about 20 mm, such as greater than about 50 mm, such as greater than about 100 mm, to 200 mm, etc.

In some examples, the semiconductor workpiece includes silicon carbide crystalline material. The silicon carbide crystalline material may have a 4H crystal structure, 6H crystal structure, or other crystal structure. The semiconductor workpiece can be an on-axis workpiece (e.g., end face parallel to the (0001) plane) or an off-axis workpiece (e.g., end face non-parallel to the (0001) plane).

Aspects of the present disclosure may make reference to a surface of the semiconductor workpiece. In some examples, the surface of the workpiece may be, for instance, a silicon face of the workpiece. In some examples, the surface of the workpiece may be, for instance, a carbon face of the workpiece.

In some examples, a semiconductor wafer may be a solid semiconductor workpiece upon which semiconductor device fabrication may be implemented. A semiconductor wafer may be a homogenous material, such as silicon carbide, and may provide mechanical support for the formation and/or carrying of additional semiconductor layers (e.g., epitaxial layers), metallization layers, and other layers to form one or more semiconductor devices. In some examples, a semiconductor wafer may have a thickness in a range of about 0.5 microns to about 1000 microns or greater, such as in a range of about 150 microns to about 400 microns, such as in a range of about 250 microns to about 350 microns. In some examples, the semiconductor wafer may include a thin semiconductor layer (e.g., about 0.5 micron or less, such as 0.1 microns to about 0.5 microns) on a carrier substrate.

Grinding is a material removal process that is used to remove material from the semiconductor wafer. Grinding may be used to reduce a thickness of a semiconductor wafer. Grinding typically involves exposing the semiconductor wafer to an abrasive containing surface, such as grind teeth on a grind wheel. Grinding may remove material of the semiconductor wafer through engagement with the abrasive surface.

Lapping is a precision finishing process that uses a loose abrasive in slurry form. The slurry typically includes coarser particles (e.g., largest dimension of the particles being greater than about 100 microns) to remove material from the semiconductor wafer. Lapping typically does not include engaging the semiconductor wafer with an abrasive-containing surface on the lapping tool (e.g., a wheel or disk having an abrasive-containing surface). Instead, the semiconductor wafer typically comes into contact with a lapping plate, or a lapping tile, usually made of metal. Lapping typically provides better planarization of the semiconductor wafer relative to grinding.

Polishing is a process to remove imperfections and create a very smooth surface with a low surface roughness. Polishing may be performed using a slurry and a polishing pad. The slurry typically includes finer particles relative to lapping, but coarser particles relative to chemical mechanical planarization (CMP). Polishing typically provides better planarization of the semiconductor wafer relative to grinding.

CMP is a type of fine or ultrafine polishing, typically used to produce a smoother surface ready, for instance, for epitaxial growth of layers on the semiconductor wafer. CMP may be performed chemically and/or mechanically to remove imperfections and to create a very smooth and flat surface with low surface roughness. CMP typically involves changing the material of the semiconductor through a chemical process (e.g., oxidation) and removing the new material from the semiconductor wafer through abrasive contact with a slurry and/or other abrasive surface or polishing pad (e.g., oxide removal). In CMP, the abrasive elements in the slurry typically remove the product of the chemical process and do not remove the bulk material of the semiconductor wafer, often leaving very low subsurface damage.

Polishing tools (e.g., such as chemical mechanical polishing (CMP) tools) may be used after grinding operations to polish and/or smooth a semiconductor wafer surface. Polishing tools, such as CMP tools, may use a combination of chemical and mechanical forces to remove excess materials from a wafer surface, ensuring desired flatness and smoothness. Polishing tools, such as CMP tools, may include a rotating platen, polishing pad, and a slurry containing abrasive particles and chemical agents. As the wafer is pressed against the polishing pad and rotated, the slurry chemically reacts with and/or mechanically removes material, resulting in a highly planar and smooth surface.

Electrochemical Mechanical Polishing (ECMP) is a specialized process used in semiconductor manufacturing for polishing and planarizing surfaces with high precision. ECMP combines the principles of electrochemical and mechanical actions to achieve highly uniform material removal rates across the surface of a semiconductor wafer. For example, a silicon carbide semiconductor wafer may be mounted or provided on a workpiece carrier, which brings the wafer into contact with a polishing pad. A slurry (including an electrolyte solution) may be applied between the semiconductor wafer and the polishing pad to facilitate the electrochemical reactions, carry away removed material, and provide lubrication for the mechanical polishing action. A bias (e.g., bias voltage and/or bias current) may be applied between the semiconductor wafer and the electrolyte solution of the slurry to drive electrochemical reactions to occur at the surface of the semiconductor wafer, leading to material dissolution. The electrochemical reactions may vary depending on the specific materials involved, but they often involve oxidation or reduction processes.

For ECMP, while the electrochemical reactions are occurring, mechanical forces may be applied to the wafer through the polishing pad. These mechanical forces help to enhance material removal and ensure a uniform polishing action across the substrate surface. As the ECMP process continues, material is gradually removed from the surface of the workpiece, resulting in planarization and smoothing of the surface. The combination of electrochemical and mechanical actions allows for precise control over material removal rates and surface finish (e.g., through control of bias (e.g., bias voltage, bias current) applied to the semiconductor wafer).

Surface processing silicon carbide semiconductor wafers may pose several challenges due to the inherent properties of the material. Silicon carbide is an extremely hard and brittle compound with a high level of abrasiveness, making the polishing process more demanding. One challenge is the potential for excessive tool wear and heat generation during surface processing, which can affect the quality of the finished product. The hardness of silicon carbide may also lead to the formation of cracks or fractures if not properly managed, impacting the structural integrity of the material. Additionally, achieving precise dimensions and surface finishes can be challenging due to the resistance of silicon carbide to abrasion. Controlling parameters such as polishing pad selection, rotational speed, slurry composition, downforce, and/or cooling mechanisms may be important to overcoming these challenges and ensuring the successful fabrication of silicon carbide components with the desired properties and performance.

In some examples, ECMP technology may use anodic oxidation of silicon carbide by providing a negative electrical contact to a counter electrode in contact with an electrolyte. This counter electrode either sits outside of the polishing pad, or no polishing pad is used at all. Overall, there is a lack of consumable materials, such as polishing pads, which are effective for applying ECMP to silicon carbide substrates.

Accordingly, example aspects of the present disclosure are directed to polishing tools (e.g., ECMP tools) that allow for polishing pads (or disks) to carry an electrical current to better facilitate the electrochemical processes utilized during ECMP. For instance, a polishing system may include an ECMP tool including a platen with a polishing pad assembly (or disk material) for polishing a semiconductor workpiece such as a silicon carbide semiconductor wafer. The polishing system may include a workpiece carrier to bring a surface of a silicon carbide semiconductor wafer against the polishing pad on the platen. The platen with the polishing pad may be operable to rotate about an axis. As will be further described herein, to help facilitate the electrochemical reactions of ECMP, the polishing pad assembly may be operable to provide an electrically conductive path for charge carriers (e.g., electrons, protons, ions, etc.) to a bias source (e.g., voltage source and/or current source). The electrically conductive path may allow for charge carriers to move from the surface, side, or backside of the polishing pad to the surface of a workpiece.

The polishing system may include a delivery system that may deposit materials onto the polishing pad. For example, the polishing system may include a slurry delivery system that deposits a slurry onto the polishing pad. The slurry may be provided to help implement the electrochemical and mechanical processes of ECMP. For example, the slurry includes an electrolyte solution that can help initiate the desired electrochemical reactions. The electrolyte solution may include an electrolyte that includes charge carriers, such as electrons, protons, ions, or other particles carrying a charge, which can be used to facilitate the electrically conductive path through the polishing pad according to the technology of the present disclosure.

To help provide mechanical polishing, the slurry may contain one or more abrasive elements. The slurry may include abrasive particles that allow a polishing pad to physically remove material from the surface, aiding in material removal and achieving the desired surface finish. These abrasive particles may include fine-grained materials, such as silicon dioxide (SiO2), alumina (Al2O3), ceria (CeO2), or other suitable nanoparticles or microparticles (e.g., KMgO₄), including those created during operation (e.g., MgO particles through decomposition of KMgO₄). During a polishing operation, the abrasive elements of the slurry may remove material from the surface of the silicon carbide semiconductor workpiece. The slurry may include an oxidizing material and/or an electrolyte.

In some embodiments, the slurry may provide for enhancing abrasive particle stabilization, electrolytic conduction, and electrochemical activity by ionic compound design. The use of tailored ionic components may allow for stabilization of the particles within the slurry. Tailoring the ionic components may be achieved by selecting cations and anions for their respective tasks for stabilizing the abrasive particle and creating an efficient electrochemical reaction. One ionic species (e.g., the cation) can bond to the abrasive particle via a direct or induced electrostatic or covalent attraction, while the anion can be tailored for highest effectivity regarding ionic conductivity and kinetics at the workpiece surface. As such, the slurry is tuned for effective polishing/grinding processes and, advantageously, does not create the environmental and safety concerns of strong oxidizers.

For instance, in some examples, a slurry may include an organic cation that can stabilize an abrasive particle within the slurry and provide the desired electrochemical properties may use a well-established chemical pathway for forming solution stable electron deficient organic species (i.e., cations). This synthetic approach uses the ability of neutral electron rich atoms, such as nitrogen, oxygen, sulfur, and phosphorous, to form sigma bonds to carbon to produce a solution stable organic cation. A neutral aromatic nitrogen, for example, can produce a stable single bond to carbon where the electron is shared between the two atoms and a net positive charge resides on the nitrogen. Such organic cations are utilized in the field of organic electrochemistry for their charged ground state and reversible redox states. The cations are paired with a carefully chosen anion to tune chemical properties like solubility and aggregation. In the solid state, they can reside as stable ionic solids, analogous to inorganic salts. These electron deficient species are tunable through molecular design to achieve the desired electrochemical properties. The positive charge functions as the primary stabilizer for abrasive slurry particles in the slurry. To this core molecular design for the cation, carefully chosen constituents are appended which serve to link the molecule to the abrasive particle, tune polarity, and optimize steric effects.

In some example embodiments, a small anion is paired with the cation to allow for effective oxidation of partially oxidized or rough surfaces of the semiconductor workpiece. The oxidized layer (e.g., of SiO₂ or other oxides including mixed oxides such as SiC: SiO₂) formed electrochemically on the semiconductor workpiece then needs to be removed chemically and/or mechanically to avoid passivation and to expose the fresh wafer surface for continuous electrochemical oxidation. In this regard, the abrasives in the slurry may interact with the oxidized layers via adsorption (chemisorption, physisorption, magnetic attraction, and/or others) and, along with the pad action, help to mechanically break down the oxidized layer to aid material removal. Some abrasive types, such as ceria, can even chemically bind to SiO₂ and facilitate material removal.

In some embodiments, some or all of the abrasive particles in the slurry can be provided to the slurry from the polishing pad or a grind disk material. For example, they may be released from the pad during a conditioning process and will be affected by the choice of anionic/cationic compounds in the slurry.

In some embodiments, the cations/anions can exhibit stabilization and attachment functions that include steric, ionic, oleophilic, or hydrophilic properties. For example, the cations or anions may function as surfactants, which are capable of sterically or electrostatically stabilizing the abrasive particles in the slurry. Surfactants may also be added to the slurry as an additional component. Depending on the pH and the isoelectric points of the workpiece (e.g., silicon carbide wafer) and the abrasive, either cationic or anionic surfactants can be used to stabilize negatively or positively charged abrasive particles, respectively. Zwitterionic surfactants, containing both cationic and anionic activity, can also be used for the same purpose, and the cationic or anionic nature of such zwitterionic surfactants can be controlled by the slurry ph. Moreover, surfactants may be water soluble, allowing the slurry to be an aqueous medium, providing the polar protic chemical environment ideal for an ECMP slurry, while offering the advantage of steric hindrance to stabilize abrasives.

In some embodiments, ionic compounds like NaCl, NaNO₃, KCl, NaNO₃, or NH₄F can be added as electrolyte components in which Na+, K+, or NH₄+ form cations and Cl-, NO3-, or F- form anions to increase the ionic strength of the slurry. The strong ionic nature of such an ECMP slurry may have added benefits to further enhance the chemical dissolution of the oxidized layer formed during ECMP. For example, when the oxidized layer contains SiO₂, the anions may act as strong nucleophiles or electron rich species to chemically attack the electron deficient Si atom of SiO₂ to promote bond breaking and hydrolysis, leading to the formation of soluble silica species such as silicic acid. Protonation and deprotonation of these soluble silica species may further enhance the ionic and nucleophilic activity of the ECMP slurry.

In some examples, to aid with mechanical polishing, the polishing pad may include an abrasive containing surface. The abrasive containing surface may include one or more abrasive elements, such as: diamond; ceramic; metal nitride; metal oxide, metal carbide; metalloid nitride; metalloid oxide; metalloid carbide; carbon group nitride; carbon group oxide; or carbon group carbide. In some examples, the polishing pad may contain catalysts that may be used to activate chemistry that contributes to the oxidation of the workpiece. Those catalysts may include, for instance: noble metals, such as platinum, gold, silver, palladium, or other metals and their oxides such as ruthenium, iridium, iron, nickel, copper, or aluminum.

The polishing system may include a workpiece electrode and a bias source (e.g., voltage source and/or current source) to initiate electrochemical reactions at the surface of the silicon carbide semiconductor wafer. The bias source may be configured to provide a bias voltage and/or a bias current between the silicon carbide semiconductor wafer and, for instance, the electrolyte solution of the slurry. The workpiece electrode may be placed in physical contact with the workpiece carrier (or another component of the system), while the bias source may be coupled to the polishing pad, the platen, or an intermediate layer therebetween. The polishing pad assembly may provide an electrically conductive path for one or more charge carriers, such as electrons, protons, ions, or other particles carrying a charge.

The structure and material of the polishing pad may be designed to help facilitate the electrically conductive path. For example, the polishing pad may include a composite material (e.g., composite matrix material). An example composite matrix material may include a polyurethane matrix, a polyester matrix, an epoxy matrix, a silicone matrix, a composite polymer matrix, a ceramic matrix, etc. The polishing pad may include one or more conductive structures to provide the electrically conductive path through the polishing pad. For example, the conductive structures may include a conductive polymer, electrically conductive carbon nanotubes, metal structures, ion conductive structures, solid electrolyte structure, or other electrically conductive structures. Additionally, or alternatively, the conductive structures may include one or more voids (e.g., apertures, pores, perforations, gaps between pad segments), which may be occupied by the electrolyte solution (e.g., provided as part of the slurry) deposited onto the polishing pad.

The electrically conductive path through the polishing pad assembly may be provided in a variety of different manners. For example, the delivery system may deliver the electrolyte to the polishing pad and a bias source may provide a bias voltage and/or a bias current between the semiconductor wafer and the electrolyte. The bias source may be electrically coupled to the electrolyte through the electrically conductive path through the polishing pad assembly.

In some examples, the polishing pad assembly may include an electrically conductive support layer. This layer may include a conductive material that provides structural support to the polishing pad while facilitating the flow of electrical current during the polishing process. The conductive material may include, for example, metal foils (e.g., copper, aluminum), carbon-based materials (e.g., carbon fiber fabrics, carbon-filled polymers), and/or ceramic materials. The support layer may be on the platen by virtue of an adhesive layer and/or a magnetic coupling. The support pad may be on the support layer by an adhesive layer (e.g., electrically conductive adhesive layer). The structural support provided by the electrically conductive support layer can help the polishing pad maintain the shape and flatness of the polishing pad, to ensure uniform contact between the pad and the wafer being polished. In some examples, the support layer may act as a protective element against chemical or electrochemical corrosion of the platen and/or the polishing pad assembly. This may further help maintain the shape and flatness of the polishing pad by avoiding deformations or compromise to shape and flatness due to corrosion. The conductivity of the support layer can help facilitate the flow of electrical current during ECMP when an electrical potential or electrical current is applied between the semiconductor wafer and the polishing pad. The electrically conductive support layer can help the electrical current to flow efficiently through the polishing pad (e.g., uniformly through the polishing pad). The bias source may be coupled to the electrically conductive support layer such that the electrically conductive path is at least partially through the electrically conductive support layer.

In some examples, the electrically conductive path to the bias source may be at least partially through an adhesive layer. For instance, the polishing pad assembly may include an adhesive layer coupled to the bias source. The adhesive layer may be positioned between the polishing pad and the platen, between the electrically conductive support layer, and/or between the polishing pad and the electrically conductive support layer. The adhesive layer can provide a strong adhesion to ensure that the polishing pad remains securely in place during the polishing process. In some examples, similar to the support layer, the adhesive layer may shield the support layer, the platen and/or the polishing pad from corrosive effects of the slurry and/or the electrochemical process. The adhesive material included in the adhesive layer depends on the materials of the polishing pad and the platen, as compatibility can help prevent delamination or other issues. By coupling the adhesive layer to the bias source, the electrically conductive path can be provided in the polishing pad as well as in the adhesive layer to facilitate the electrochemical reactions of the EMCP processes.

In some examples, the electrically conductive path to the bias source may be at least partially through the platen. For example, the platen may be electrically coupled to the bias source. In this manner, the electrically conductive path can be provided in the polishing pad as well as at least partially in the platen, as well as any intermediate layers (if any) included between the polishing pad and the platen (e.g., support layer and/or adhesive layer(s)).

As described above, the electrically conductive path to the bias source may be provided by electrical contact with the platen (e.g., from the bottom of the polishing pad assembly). The electrically conductive path to the bias source may be provided by electrical contact from other positions without deviating from the scope of the present disclosure, such as through a side of the polishing pad assembly (e.g., polishing pad, adhesive layer, and/or support layer) and/or through a top of the polishing pad assembly (e.g., through the workpiece carrier, such as through a conductive path in a retaining ring of the workpiece carrier).

The electrically conductive path provided by the polishing pad described herein can be utilized within a polishing system to implement an improved ECMP process for silicon carbide substrates. For example, a workpiece carrier of the polishing system may be utilized to provide the surface of a silicon carbide semiconductor wafer onto the polishing pad. The delivery system may provide an electrolyte (e.g., contained in a slurry) onto a surface of the polishing pad. Using the workpiece electrode and the bias source, the polishing system may provide a bias voltage and/or a bias current between the workpiece and the electrolyte through the electrically conductive path for charge carriers. As described herein, this can help cause the desired electrochemical reactions at the surface of the silicon carbide semiconductor wafer. While the electrochemical reactions are occurring, mechanical forces may also be applied to the silicon carbide semiconductor wafer through relative motion of the polishing pad and the semiconductor wafer. The combination of the electrochemical reactions and the mechanical forces can help to enhance material removal and ensure a uniform polishing action across the wafer surface.

Aspects of the present disclosure provide a number of technical effects and benefits. For instance, the technology described herein allows polishing pad assemblies or disks to carry an electric current through the electrically conductive path at least partially in the polishing pad assembly. Such polishing pad assemblies can be used to more effectively facilitate the processes needed for ECMP by providing more uniform and consistent electrochemical reactions at the surface of a silicon carbide workpiece. This may result in enhanced planarization or other surface processing of a silicon carbide workpiece (e.g., semiconductor wafer) than other ECMP technologies that utilize a counter electrode outside of the polishing pad or forgo the use of a polishing pad all together. Ultimately, the technology of the present disclosure can improve the availability of ECMP methods, which have considerable advantages for the environment and processing costs compared to CMP.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, structure, region, or substrate is referred to as being “on” or extending “onto” another element, it may be directly on or extend directly onto the other element or intervening elements may also be present and may be only partially on the other element. In contrast, when an element is referred to as being “directly on” or extending “directly onto” another element, there are no intervening elements present, and may be partially directly on the other element. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

As used herein, a first structure “at least partially overlaps” or is “overlapping” a second structure if an axis that is perpendicular to a major surface of the first structure passes through both the first structure and the second structure. A “peripheral portion” of a structure includes regions of a structure that are closer to a perimeter of a surface of the structure relative to a geometric center of the surface of the structure. A “center portion” of the structure includes regions of the structure that are closer to a geometric center of the surface of the structure relative to a perimeter of the surface. “Generally perpendicular” means within 15 degrees of perpendicular. “Generally parallel” means within 15 degrees of parallel.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, n type material has a majority equilibrium concentration of negatively charged electrons, while p type material has a majority equilibrium concentration of positively charged holes. Some material may be designated with a “+” or “−” (as in n+, n−, p+, p−, n++, n−−, p++, p−−, or the like), to indicate a relatively larger (“+”) or smaller (“−”) concentration of majority carriers compared to another layer or region. However, such notation does not imply the existence of a particular concentration of majority or minority carriers in a layer or region.

Aspects of the present disclosure may refer to a “pad.” In some cases, a pad with increased stiffness, thickness, or other attributes may be commonly referred to as a “disk.” However, in the present disclosure, the terms “pad” and “disk” and “disc” may be used interchangeably without altering the scope of the present disclosure.

In the drawings and specification, there have been disclosed typical embodiments and, although specific terms are employed, they are used in a generic and descriptive sense only and not for purposes of limitation of the scope set forth in the following claims.

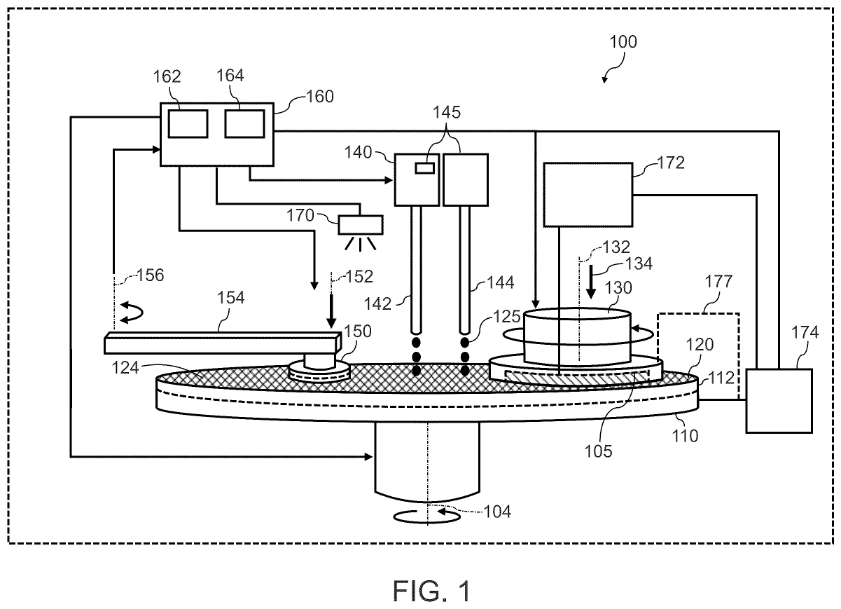

FIG. 1 depicts an example polishing system 100 for a semiconductor workpiece 105 according to example embodiments of the present disclosure. The polishing system 100 is an ECMP system operable to perform one or more polishing operations for the semiconductor workpiece 105. The semiconductor workpiece 105 may be a silicon carbide semiconductor workpiece such as, for example, a silicon carbide wafer. The silicon carbide wafer may include 4H silicon carbide, 6H silicon carbide or other crystal structure. The semiconductor workpiece 105 may be doped or undoped. In some examples, the polishing system 100 includes a platen 110 with a polishing pad 120, a workpiece carrier 130, a delivery system 140, a conditioning head 150, and a controller 160.

More specifically, the polishing system 100 includes the platen 110. The platen 110 may be operable to rotate about an axis 104. The platen 110 may be operable to rotate about the axis 104 in either a clockwise or counterclockwise direction. In some examples, the platen 110 may rotate, for instance, at a rotational speed in a range of about 15 rpm to about 10000 rpm, such as about 15 rpm to about 7500 rpm, such as about 15 rpm to about 2000 rpm, such as about 15 rpm to about 1000 rpm, such as about 15 rpm to about 500 rpm, such as about 15 rpm to about 120 rpm.

The polishing system 100 includes a polishing pad assembly 124 on the platen 110. For instance, the platen 110 may include a receptacle 112. The receptacle 112 may be configured to hold a polishing pad 120 for an ECMP process. The receptacle 112 may be a surface configured to support or receive the polishing pad 120 (and/or one or more other layers of a polishing pad assembly, such as a support layer and/or adhesive layer(s)). In some examples, the receptacle 112 may be a planar surface that supports the polishing pad 120. The polishing pad 120 may be a part of a polishing pad assembly that includes the polishing pad 120 and one or more additional layers, such as one or more support layers and/or one or more adhesive layers.

The polishing pad 120 may provide a surface for polishing the semiconductor workpiece 105. The polishing pad 120 may include durable and chemically resistant materials such as polyurethane and/or polyether ether ketone (PEEK) material. The polishing pad 120 may have a surface with a specified roughness and porosity to facilitate polishing a semiconductor workpiece 105 (e.g., a silicon carbide semiconductor wafer). The polishing pad 120 may have one or more wear-resistant layers (e.g., diamond layers, diamond-like carbon layers, ceramic layers, etc.). The polishing pad 120 may include grooves or dimples to increase slurry distribution and reduce edge effects during the ECMP process. As further described herein, the polishing pad 120 includes one or more structures to provide an electrically conductive path for charge carriers for instance, through electrical conduction or by providing structures (e.g., voids) to accommodate an electrolyte solution.

The polishing pad 120 may include a cushioning layer (e.g., foam or rubber), in some examples, to facilitate adaptation of the polishing pad 120 to the topography of the semiconductor workpiece 105, providing improved planarity of the semiconductor workpiece 105.

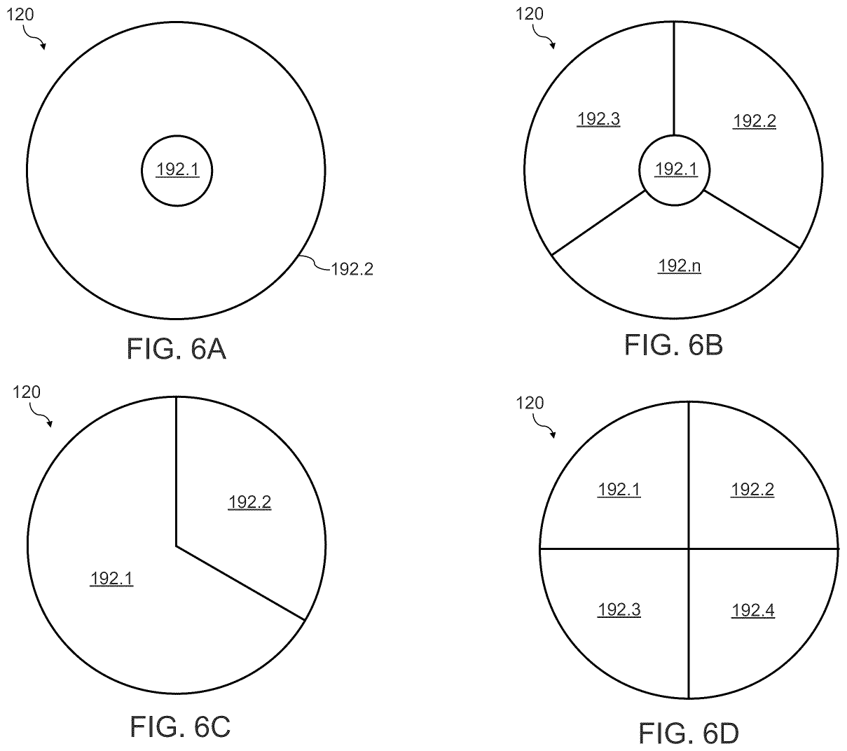

The polishing pad 120 may have a diameter. The diameter may be greater than a size of the semiconductor workpiece 105. The polishing pad 120 may have a diameter in a range of, for instance, about 150 mm to about 820 mm, such as in a range of about 150 mm to about 400 mm, such as in a range of about 150 mm to about 300 mm. In some examples, the diameter of the polishing pad 120 may be smaller or nearly the same size as the diameter of the platen 110 (FIG. 1). In some examples, the diameter of the polishing pad 120 may be smaller than the diameter of the platen 110 and/or a support layer (e.g., support layer 610 (FIGS. 6-9) to allow for top contact of the bias source to the platen 110 and/or the support layer. However, the diameter of the polishing pad 120 may be larger than the diameter of the platen 110 without deviating from the scope of the present disclosure. In some examples, the polishing pad 120 may have a thickness in a range of about 1 millimeter to about 40 millimeters, such as in a range 1 millimeters to about 20 millimeters, such as in a range of about 1 millimeters to about 7 millimeters.

In some examples, the polishing pad 120 may include an abrasive containing surface. The abrasive surface may include an abrasive containing material. The abrasive containing material may be suitable for polishing or surface processing of silicon carbide. The abrasive containing material may include a plurality of abrasive elements (e.g., abrasive particles) in a host material or matrix. In some examples, the host material may include one or more vitreous material, metal, resin, and/or other sintered material and/or organic material. In some examples, the abrasive elements may be diamond, or a diamond coated material. In some examples, the abrasive elements may include a ceramic material. Example ceramic materials may include, for instance, boron carbide (B₄C) and cubic boron nitride (BN). In some examples, the abrasive elements may include one or more metal oxides (sintered and/or unsintered). In some embodiments, the abrasive elements may include silica, ceria, zirconia, alumina, silicon carbide, nitrates, and/or other carbides and in general one or more of: (i) diamond; (ii) ceramic; (iii) metal nitride; (iv) metal oxide, (v) metal carbide; (vi) metalloid nitride; (vii) metalloid oxide; (viii) metalloid carbide; (ix) carbon group nitride; (x) carbon group oxide; or (xi) carbon group carbide.

In some examples, the polishing pad 120 has an abrasive storing material (e.g., material with one or more voids). The abrasive storing material may hold abrasive particles or elements (e.g., from a slurry used in an ECMP operation). The abrasive particles or elements held by the polishing pad assembly 124 may provide an abrasive surface for performing an ECMP operation. In some examples, the polishing pad assembly 124 does not include a surface with abrasive elements.

In some examples, the polishing pad 120 may provide an electrically conductive path for one or more charge carriers through the polishing pad 120 to a bias source 174, allowing for charge carriers to move from the surface, side, or backside of the polishing pad 120 to the surface of a workpiece 105. Methods of conduction of charge carriers can include electronic transport of electrons or holes, ionic conduction of protons or other ions, fluid transport of any particles carrying a charge. Charge transport may be a general property, independent of the driving forces such as electrical potential, diffusion, or thermal-, pressure-, and other gradients.

In some examples, the resistivity of the electrically conductive path through a thickness of the polishing pad 120 may be in a range of about 1 microOhm/cm² to about 500 Ohm/cm². The resistivity through the thickness of the polishing pad 120 may be different for different types of charge carriers. In some examples, the resistivity of the electrically conductive path through a thickness of the polishing pad 120 may be in a range from about 1 microOhm/cm² to about 0.1 Ohm/cm². In some examples, the resistivity of the electrically conductive path through a thickness of the polishing pad 120 may be in a range from about 0.1 Ohm/cm² to about 200 Ohm/cm², such as about 1 Ohm/cm² to about 100 Ohm/cm², such as about 2 Ohm/cm² to about 50 Ohm/cm². In some examples, the resistivity of the electrically conductive path through a thickness of the polishing pad 120 may be in a range from about 0.1 Ohm/cm² to about 500 Ohm/cm², such as about 2 Ohm/cm² to about 200 Ohm/cm², such as about 4 Ohm/cm² to about 100 Ohm/cm².

In some examples the polishing pad 120 may have a sheet resistance in a radial direction of the polishing pad in a range of about 6 microOhm·m/m to about 200 Ohm·m/m. The sheet resistance in the radial direction of the polishing pad 120 may be different for different types of charge carriers. In some examples, the polishing pad 120 may have a sheet resistance in a range of about 6 microOhm·m/m to about 250 milliOhm·m/m. In some examples, the polishing pad 120 may have a sheet resistance in a range of about 0.25 Ohm·m/m to about 2.0 Ohm·m/m, such as about 0.5 Ohm·m/m to about 1 Ohm·m/m, such as about 0.5 Ohm·m/m to about 0.75 Ohm·m/m in a radial direction of the polishing pad 120. In some examples, the polishing pad 120 may have a sheet resistance in a range of about 0.25 Ohm·m/m to about 200 Ohm·m/m, such as about 0.5 Ohm·m/m to about 100 Ohm·m/m, such as about 0.5 Ohm·m/m to about 75 Ohm·m/m in a radial direction of the polishing pad 120. The electrically conductive path provided by the polishing pad 120 in these ranges may provide for greater uniformity in the electrochemical reactions occurring at the workpiece 105.

In some examples, the material of the polishing pad 120 may include metal or metallic elements, a matrix, or metal bonds. The metal materials can contain catalysts that may be used to activate chemistry that contributes to the oxidation of the workpiece 105. Those metals may include, for instance, noble metals, such as platinum, gold, silver, palladium, or other metals and their oxides, such as ruthenium, iridium, iron, nickel, copper, or aluminum. In these cases, the electrical resistivity through a thickness of the polishing pad 120 can be in the range of 1 micro-Ohm/cm² to 100 milli-Ohm/cm² or higher, and the sheet resistance in a radial direction can be in a range of 6 microOhm m/m to about 250 milliOhm m/m or higher.

In some examples, a surface polishing pad with a large resistance may be compensated with the increased flow of electrolyte (e.g., electrolyte slurry). This may allow the electrolyte fluid to move through voids (e.g., open pore system, channels, apertures, holes, etc.) in the polishing pad 120, contributing to conductive paths in the polishing pad 120.

The delivery system 140 may be used to deliver a slurry to the polishing pad 120 held on the platen 110 during an ECMP process. The slurry may be delivered, for instance, from a slurry delivery outlet 142. The slurry may include abrasive particles that allow a polishing pad to physically remove material from the surface, aiding in material removal and achieving the desired surface finish. These abrasive particles may include fine-grained materials such as silicon dioxide (SiO2), alumina (Al2O3), ceria (CeO2), and other suitable nanoparticles or microparticles. Other suitable slurries with one or more abrasive elements (e.g., abrasive particles) may be used without deviating from the scope of the present disclosure.

The slurry may include an electrolyte solution. The electrolyte solution may include electrolytes that aid in the polishing process by aiding in material removal and controlling surface finish. The electrolytes include charge carriers, such as electrons, protons, ions, or other particles carrying a charge, which can be used to facilitate the electrically conductive path through the polishing pad according to the technology of the present disclosure.

The delivery system 140 may further include one or more fluid delivery outlets 144. The fluid delivery outlets 144 may be configured to provide one or more fluids (e.g., coolant, additive, lubricant, etc.) to the polishing pad 120 during a polishing process.

In some examples, the delivery system 140 may include an additive delivery system 145 configured to deliver one or more additives either with the slurry through the slurry delivery outlet 142 or separate from the slurry through the fluid delivery outlet 144. In some examples, the additive may be, for instance, one or more of an oxidizing agent, an etchant, an abrasive containing additive, an actuatable additive, a surfactant, or a lubricant.

Those of ordinary skill in the art, using the disclosures provided herein, will understand that the delivery system 140 may deliver materials (e.g., slurry) to the polishing pad 120 in various ways without deviating from the scope of the present disclosure, such as from a plurality of fluid delivery outlets, from apertures in the platen and/or the polishing pad, or from other fluid delivery techniques.

The polishing system 100 includes a workpiece carrier 130. The workpiece carrier 130 is operable to bring one or more semiconductor workpieces 105 into contact with the polishing pad 120 to implement a polishing process. In some examples, the workpiece carrier 130 may be operable to hold a semiconductor workpiece 105 for single wafer processing. In some examples, the workpiece carrier 130 may be operable to hold a plurality of semiconductor workpieces 105 for batch processing. The workpiece carrier 130 may include a head and a retaining ring, in some embodiments.

The workpiece carrier 130 may be operable to rotate the semiconductor workpiece 105 about an axis 132. The axis 132 is not aligned with the axis 104 associated with the platen 110. The workpiece carrier 130 may be operable to rotate the semiconductor workpiece 105 about the axis 132 in either a clockwise or counterclockwise direction. In some examples, the workpiece carrier 130 may rotate, for instance, at a rotational speed in range of about 15 rpm to about 10000 rpm, such as about 15 rpm to about 7500 rpm, such as about 15 rpm to about 2000 rpm, such as about 15 rpm to about 1000 rpm, such as about 15 rpm to about 500 rpm, such as about 15 rpm to about 120 rpm. The workpiece carrier 130 may rotate in the same direction as the platen 110 or in a different direction relative to the platen 110.

The workpiece carrier 130 may be able to provide a downforce 134 of the semiconductor workpiece 105 against the polishing pad 120. The downforce 134 of the workpiece carrier 130 may be controlled to adjust the polishing rate of the polishing process of the semiconductor workpiece 105.

The workpiece carrier 130 may also oscillate in a lateral direction along the surface of the polishing pad 120. This will allow exposure of the semiconductor workpiece 105 to different portions of the polishing pad 120 (e.g., at different radii of the polishing pad 120) during a polishing operation.

In some examples, the workpiece carrier 130 may include an electrically conductive head that may be used to provide a bias (e.g., bias voltage and/or a bias current) from a bias source (e.g., bias source 174) to the semiconductor workpiece 105. Other suitable mechanisms for providing a bias to the workpiece 105 may be implemented without deviating from the scope of the present disclosure.

The polishing system 100 may include a conditioning head 150. The conditioning head 150 may rotate about an axis 152, such that the conditioning head 150 rotates along the surface of the polishing pad 120 (e.g., in either a clockwise or counterclockwise direction). In some examples, the conditioning head 150 may be on a swing arm 154 that may swing about an axis 156 to move the conditioning head 150 to different locations on the polishing pad 120. The conditioning head 150 may include an abrasive-containing material that is used to condition or dress the polishing pad 120 as the polishing pad 120 is subject to glazing during a polishing process. In some examples, the conditioning head 150 may be conductively coupled to the bias source (e.g., bias source 174) to provide a bias to the electrolyte, polishing pad 120, and/or semiconductor wafer 105.

The polishing system 100 includes one or more control devices, such as a controller 160. The controller 160 may include one or more processors 162 and one or more memory devices 164. The one or more memory devices 164 may store computer-readable instructions that when executed by the one or more processors 162 cause the one or more processors 162 to perform one or more control functions, such as any of the functions described herein. The controller 160 may be in communication with various other aspects of the polishing system 100 through one or more wired and/or wireless control links. For instance, the controller 160 may control the platen 110, the workpiece carrier 130, the delivery system 140, the conditioning head 150, and/or a bias source 174 to implement polishing processes according to examples of the present disclosure. In some examples, the controller 160 may control the temperature, heating or cooling, of the platen 110, workpiece carrier 130, and/or delivery system 140 to influence reactivity and stability of components in the electrochemical mechanical polishing process.

For instance, in some examples, the controller 160 may control the delivery system 140 to deliver a material to the polishing pad 120. For instance, the controller 160 may control the delivery system 140 to provide a slurry to the polishing pad 120 (e.g., through one or more of slurry delivery outlet 142 and/or fluid delivery outlet 144).

To facilitate ECMP, the polishing system 100 may include a workpiece electrode 172 and a bias source 174. The workpiece electrode 172 may include an electrical conductor that provides an electrical contact to, for example, the semiconductor workpiece 105. The workpiece electrode 172 is illustrated as being separate from the workpiece carrier 130 for purposes of illustration and discussion. Those of ordinary skill in the art, using the disclosures provided herein, will understand that the workpiece electrode 172 may be a part of the workpiece carrier 130 (e.g., a metal or electrically conductive path in the workpiece carrier 130 in electrical contact with the semiconductor workpiece 105).

The bias source 174 includes a device or circuit that provides a bias voltage and/or bias current between the semiconductor workpiece 105 (e.g., via the workpiece electrode 172) and the electrolyte of the slurry (e.g., via the polishing pad 120). For instance, the bias source 174 may be a voltage source configured to provide a controlled bias voltage between the semiconductor workpiece 105 and an electrolyte (e.g., electrolyte slurry, solid electrolyte). The bias source 174 may be a current source configured to provide a controlled bias current to the semiconductor workpiece 105. In some examples, the bias voltage may be in a range of about 0.5 V to about 20 V, such as about 0.5 V to about 2 V, such as about 1V to about 10 V, such as about 8 V to about 20V. In some examples, the bias voltage and/or the bias current can be used to control selectivity of the removal process and/or to control other chemical processes in the electrolyte solution or at surfaces in contact with the electrolyte solution. In some examples, the workpiece electrode 172 may be placed in physical contact with the workpiece 105, while the bias source 174 may be coupled to an electrolyte solution (e.g., in a slurry) through the polishing pad 120, the platen 110, an intermediate layer therebetween. The bias source 174 may be coupled to the electrolyte solution in any suitable manner, such as through the bottom of the polishing pad assembly 124, a side of the polishing pad assembly 124 (e.g., polishing pad, adhesive layer, and/or support layer) and/or through a top of the polishing pad assembly. For instance, as indicated by dashed line 177, the bias source 174 may be coupled to the electrolyte solution through the workpiece carrier 130 (e.g., through a conductive path in a retaining ring of the workpiece carrier). In some examples, the bias source 174 may be coupled to the electrolyte solution through the conditioning head 150 and/or electrode in contact with the polishing pad 120 or electrolyte solution.

In some examples, an electrochemical reaction rate on the semiconductor workpiece 105 may be controlled by controlling the bias source 174. For instance, a bias current may be controlled to provide an increased reaction rate or a decreased reaction rate during a surface processing operation. For instance, a high bias current may lead to faster reaction rate and higher polishing rates. However, a lower bias current may lead to a slower reaction rate to allow time for mechanical removal (e.g., through abrasive elements in a slurry) of reactants on the workpiece 105 during the surface processing operation. Control of the bias current may allow for the bias voltage to fluctuate as needed to provide a constant bias current or regulated bias current to the semiconductor workpiece 105. The bias current and/or the bias voltage may be controlled or regulated to control and/or calculate or otherwise determine material removal rates from the workpiece 105.

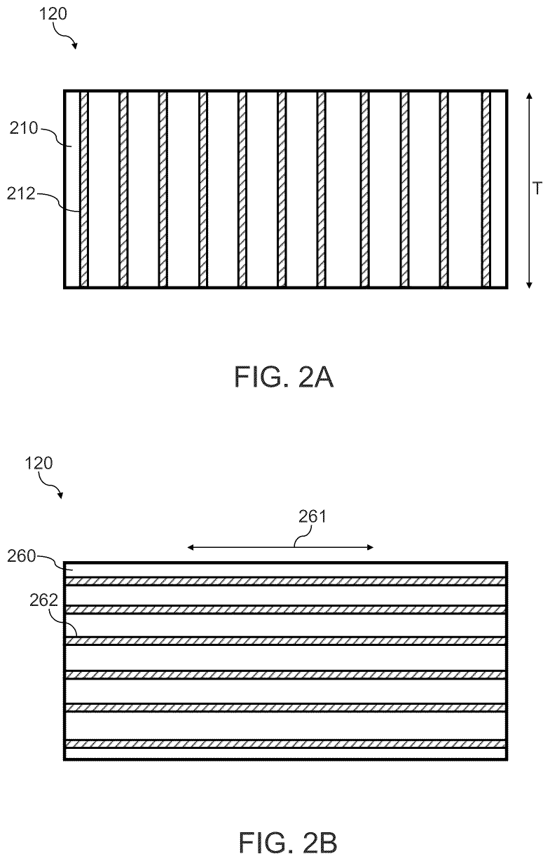

The structure and material of the polishing pad 120 can help facilitate the electrically conductive path to the bias source 174. For example, FIG. 2A depicts a cross-sectional view of an example embodiment of the polishing pad 120 according to example aspects of the present disclosure. The polishing pad 120 may include a composite matrix material 210. An example composite matrix material 210 may include a polyurethane matrix, a polyester matrix, an epoxy matrix, a silicone matrix, a composite polymer matrix, a ceramic matrix, etc. The polishing pad 120 may include one or more conductive structures 212 to provide an electrically conductive path through the polishing pad 120. For example, the conductive structures 212 may include at least one of: (i) a conductive polymer; (ii) one or more electrically conductive carbon nanotubes; (iii) one or more metal structures in the composite matrix material 210; (iv) one or more ion conductive materials; (v) solid electrolyte structure; (vi) fluid conductive material (e.g., in one or more voids), or other electrically conductive structures 212.

As shown in FIG. 2A. the conductive structures 212 may be oriented vertically within the composite matrix material 210 (e.g., through a thickness T of the polishing pad 120). Vertical orientation may be defined as being generally perpendicular to the surface of the polishing pad 120 intended to contact the semiconductor workpiece 105.

FIG. 2B depicts a cross-sectional view of another example embodiment of the polishing pad 120 according to example aspects of the present disclosure. The polishing pad 120 may include a composite matrix material 260 similar to composite matrix material 250. The polishing pad 120 may include one or more conductive structures 262 (e.g., conductive polymer, electrically conductive carbon nanotubes, metal structures, ion conductive material, solid electrolyte structure, fluid conductive material, etc.) to provide an electrically conductive path through the polishing pad 120. As shown in FIG. 2B, the conductive structures 262 may be oriented horizontally within the composite matrix material 260. Horizontal orientation may be defined as being generally parallel to the surface of the polishing pad 120 intended to contact the semiconductor workpiece 105. The conductive structures 262 may at least partially provide a lateral conductive path through the polishing pad 120.

Additionally, or alternatively, the electrically conductive path through the polishing pad 120 may include one or more voids in the polishing pad 120. The one or more voids may be operable to accommodate an electrolyte. For example, the one or more apertures may include at least one of: (i) one or more pores; (ii) one or more perforations; (iii) one or more apertures; or (iv) one or more gaps between segments of the polishing pad.

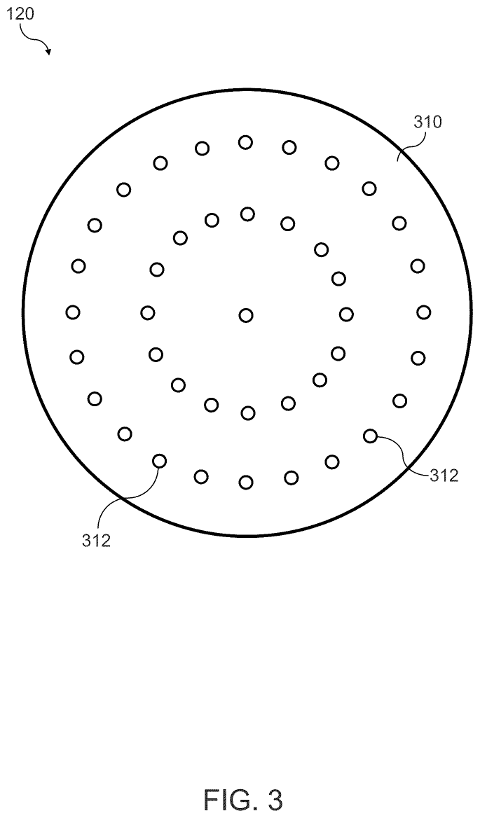

FIG. 3 depicts a top-down view of an example polishing pad 120 according to example aspects of the present disclosure. The polishing pad 120 may include a composite matrix material 310 (e.g., polymer) similar to that of composite matrix material 210 and 250. The polishing pad 120 may include one or more voids 312. As shown in FIG. 3, the voids 312 may include, for instance, one or more holes, or apertures in the polishing pad 120. The holes or apertures may be intentionally formed in the polishing pad 120. For ECMP, the electrolyte solution of the slurry provided to the polishing pad 120 can fill the holes or apertures of the polishing pad 120 to help create the electrically conductive path through the polishing pad 120.

FIG. 4 depicts a top-down view of another example polishing pad 120 according to example aspects of the present disclosure. The polishing pad 120 may include a composite matrix material 410 (e.g., polymer) similar to that of composite matrix material 210, 250, and 310. The polishing pad 120 may include one or more voids 412. As shown in FIG. 4, the voids 412 may include gaps between segments 414A-C of the polishing pad 120. The gaps provide voids in the polishing pad 120 that may extend from a first surface polishing pad 120 (e.g., a top surface shown in FIG. 4) to a second surface of the polishing pad 120 (e.g., a bottom surface).

The gaps may be intentionally formed in the polishing pad 120 using various manufacturing processes. For instance, as shown in FIG. 4, the gaps may be formed as a plurality of concentric rings within the polishing pad 120. For ECMP, the electrolyte solution of the slurry provided to the polishing pad 120 can fill the gaps of the polishing pad 120 to help create the electrically conductive path through the polishing pad 120.

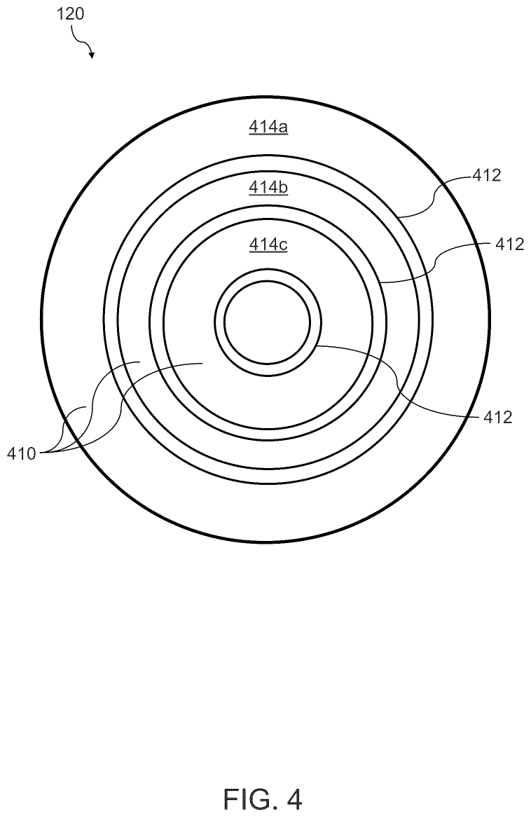

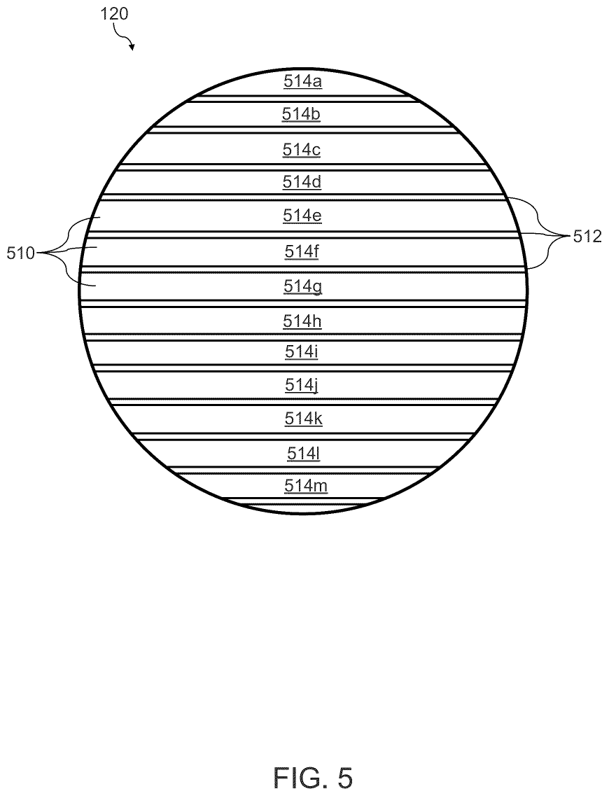

In some examples, the gaps in the polishing pad 120 may be formed in shapes or arrangements other than concentric rings. For instance, FIG. 5 depicts a top-down view of another example polishing pad 120 according to example aspects of the present disclosure. The polishing pad 120 may include a composite matrix material 510 (e.g., polymer) similar to that of composite matrix material 210, 250, 310, and 410. The polishing pad 120 may include one or more voids 512. As shown in FIG. 5, the voids 312 may include gaps between segments 514a-m of the polishing pad 120. The gaps provide voids in the polishing pad 120 that may extend from a first surface polishing pad 120 (e.g., a top surface shown in FIG. 5) to a second surface of the polishing pad 120 (e.g., a bottom surface).

Rather than the concentrically ringed gaps as in FIG. 4, the gaps shown in FIG. 5 are generally parallel to one another. The electrolyte solution of the slurry provided to the polishing pad 120 can fill the parallel gaps of the polishing pad 120 to help create the electrically conductive path through the polishing pad 120.

Other suitable regular and/or irregular patterns of voids may be provided in the polishing pad 120 without deviating from the scope of the present disclosure. The patterns may include patterns of voids extending in one or more directions. In some examples the pattern may be a net pattern, cross hatch pattern, honeycomb pattern, or other suitable pattern. In some examples, the patterns may follow a density of open volume gradient to allow for control of bias current flow. In some examples, the voids are provided as part of the composite material. For instance, the composite material may be a porous material having a porosity to provide voids for accommodating the electrolyte as the electrolyte fills the voids.

In some examples, the polish pad 120 may include a plurality of zones. Each zone may be associated with a different resistivity and/or coupled to a different bias source (e.g., voltage source or current source) so that the bias in each zone can be independently controlled or different from one another. This may allow for high current flow, for instance, and increased material removal on the workpiece in a first portion of the workpiece 105 (e.g., a center portion of the workpiece) relative to a second portion (e.g., a peripheral portion) of the workpiece 105.

In some examples, each zone may be associated with a different resistivity and/or sheet resistance. In this way, each zone may provide a different bias to the electrolyte solution and/or workpiece 105 relative to other zones, despite being coupled to a common bias source. For instance, the different resistances will result in different bias currents at the same bias voltage in the different conductive paths provided through the different zones. However, in some examples, each zone may be electrically coupled to a different bias source without deviating from the scope of the present disclosure.

FIGS. 6A, 6B, 6C, and 6D depict example patterns of zones 192.1, 192, . . . 192.n on a polishing pad 120 according to examples of the present disclosure. For instance, in FIG. 6A, the polishing pad 120 includes a first zone 192.1 that is a center zone in a central portion of the polishing pad 120. The polishing pad 120 includes a second zone 192.2 that is a peripheral zone in a peripheral portion of the polishing pad 120. The first zone 192.1 and the second zone 192.2 may have different resistivity and/or different sheet resistance in one or more directions (e.g., in a radial direction, lateral direction, or through the thickness of the polishing pad 120). In some examples, the first zone 192.1 and the second zone 192.2 may be coupled to different bias sources.

In FIG. 6B, the polishing pad 120 includes a first zone 192.1 that is a center zone in a central portion of the polishing pad 120. The polishing pad 120 includes a second zone 192.2, third zone 192.3, and fourth zone 192.4 that are peripheral zones in different azimuthal locations about a peripheral portion of the polishing pad 120. The first zone 192.1, the second zone 192.2, the third zone 192.3, and/or the fourth zone 192.4 may have different resistivity and/or different sheet resistance in one or more directions (e.g., in a radial direction, lateral direction, or through the thickness of the polishing pad 120). In some examples, the first zone 192.1, the second zone 192.2, the third zone 192.3, and/or the fourth zone 192.4 may be coupled to different bias sources.

In FIG. 6C, the polishing pad 120 includes a first zone 192.1 and a second zone 192.2. The first zone 192.1 and the second zone 192.2 may have different sizes. The first zone 192.1 and the second zone 192.2 may have different resistivity and/or different sheet resistance in one or more directions (e.g., in a radial direction, lateral direction, or through the thickness of the polishing pad 120). In some examples, the first zone 192.1 and the second zone 192.2 may be coupled to different bias sources.

In FIG. 6D, the polishing pad 120 includes a first zone 192.1, a second zone 192.2, third zone 192.3, and a fourth zone 192.4. The first zone 192.1, the second zone 192.2, the third zone 192.3, and/or the fourth zone 192.4 may have different resistivity and/or different sheet resistance in one or more directions (e.g., in a radial direction, lateral direction, or through the thickness of the polishing pad 120). In some examples, the first zone 192.1, the second zone 192.2, the third zone 192.3, and/or the fourth zone 192.4 may be coupled to different bias sources.

FIGS. 6A, 6B, 6C, and 6D depict example arrangements of zones on a polishing pad 120 for purposes of illustration and discussion. A variety of regular or irregular patterns of zones may be used on the polishing pad 120 without deviating from the scope of the present disclosure.

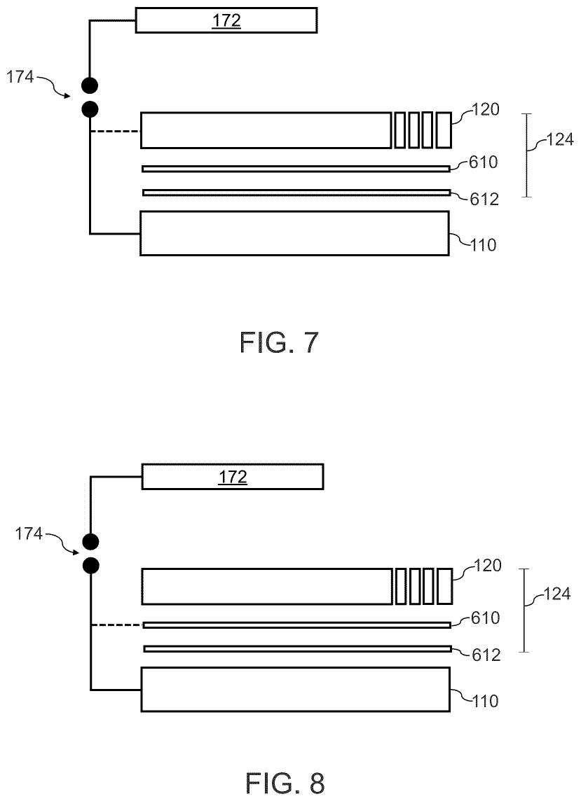

FIG. 7 depicts a cross-sectional view of a polishing pad assembly 124 on the platen 110. The polishing pad assembly 124 includes the polishing pad 120 and any intermediate layers according to example aspects of the present disclosure. FIG. 7 provides an exploded view of the various potential layers of the polishing pad assembly 124 and is not intended to suggest any spacing requirements between the layers.

The polishing pad assembly 124 may include an electrically conductive support layer 610. The electrically conductive support layer 610 may include a conductive material that provides structural support to the polishing pad 120 while facilitating the flow of electrical current during ECMP. The conductive material may include, for example, metal foils (e.g., copper, aluminum) and/or carbon-based materials (e.g., carbon fiber fabrics, carbon-filled polymers) and/or ceramic materials. The structural support provided by the electrically conductive support layer 610 can help the polishing pad 120 maintain its shape and flatness. In some examples, the support layer 610 may act as a protective element against chemical or electrochemical corrosion of the platen 110 and/or the polishing pad 120. This may further help maintain the shape and flatness of the polishing pad 120 by avoiding deformations or compromise to shape and flatness due to corrosion. This can help provide uniform contact between the surface of the polishing pad 120 and the semiconductor workpiece 105 being polished. The conductivity of the electrically conductive support layer 610 helps facilitate the flow of electrical current during ECMP when an electrical voltage and/or current is applied between the semiconductor workpiece 105 and the polishing pad 120. The electrically conductive support layer 610 can help the electrical current to flow efficiently through the polishing pad 120.

The polishing pad assembly 124 may include an adhesive layer 612. The adhesive layer 612 may be positioned between the polishing pad 120 and the platen 110. In some examples, the adhesive layer 612 may be positioned between the electrically conductive support layer 610 of the polishing pad 120 and the platen 110. The adhesive layer 612 may provide adhesion to ensure that the polishing pad 120 remains securely in place during the polishing process.

FIG. 7 illustrates the adhesive layer 612 between the platen 110 and the conductive support layer 610 for purposes of illustration and discussion. In some examples, the adhesive layer 612 may be between the conductive support layer 610 and the support pad 120. In some examples, there may be multiple adhesive layers (e.g., a first adhesive layer between the conductive support layer 610 and the platen 110 and a second adhesive layer between the conductive support layer 610 and the polishing pad 120.

The electrically conductive path to the bias source 174 may be provided through the one or more layers. For example, the delivery system 140 of the polishing system 100 can deliver the slurry to the polishing pad 120. The slurry may include an electrolyte solution. The application of the electrolyte solution allows the electrolyte solution to fill the voids 312 (FIG. 3), 412 (FIG. 4), 512 (FIG. 5), of the polishing pad 120. The bias source 174 can provide a bias voltage and/or a bias current between the semiconductor wafer 105 (e.g., via the workpiece electrode 172) and the electrolytes. The bias source 174 may be electrically coupled to the electrolytes through the electrically conductive path through the polishing pad 120, as depicted in FIG. 7.

In some examples, as depicted in FIG. 8, the bias source 174 may be coupled to the electrically conductive support layer 610 such that the electrically conductive path is at least partially through the electrically conductive support layer 610.

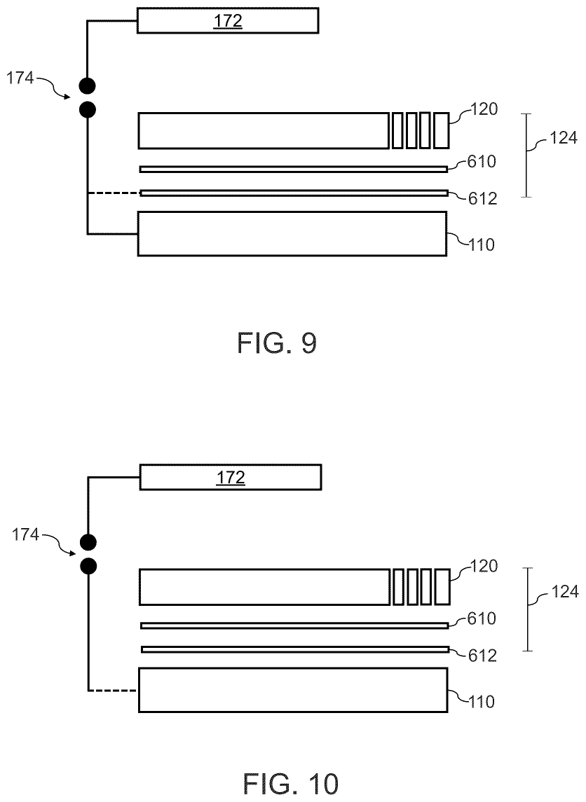

In some examples, as depicted in FIG. 9, the electrically conductive path to the bias source 174 may be at least partially through the adhesive layer 612. By coupling the adhesive layer 612 to the bias source 174, the electrically conductive path may be at least partially through the adhesive layer 612 to facilitate the electrochemical reactions of the EMCP processes of polishing system 100.

In some examples, as depicted in FIG. 10, the electrically conductive path to the bias source 174 may be at least partially through the platen 110. For example, the platen 110 may be electrically coupled to the bias source 174. In this manner, the electrically conductive path through the polishing pad 120 may be at least partially through the platen 110, as well as any intermediate layers (if any) included between the polishing pad 120 and the platen 110 (e.g., electrically conductive support layer 610, adhesive layer 612).

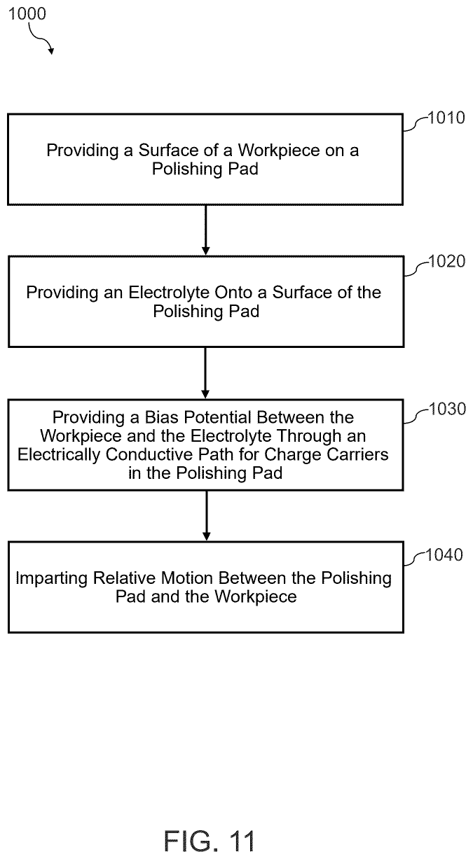

FIG. 11 depicts a flow chart of an example method 1000 according to example embodiments of the present disclosure. The method 1000 includes a method for polishing the surface of a workpiece. The method 1000 may be implemented, for instance, using the polishing system 100 of FIG. 1. The method 1000 depicts operations performed in a particular order for purposes of illustration and discussion. Those of ordinary skill in the art, using the disclosures provided herein, will understand that the operations of any of the methods described herein may be adapted, expanded, performed simultaneously, omitted, rearranged, include steps not illustrated, and/or modified in various ways without deviating from the scope of the present disclosure.

At 1010, the method 1000 may include providing the surface of a workpiece on a polishing pad. For instance, a workpiece may be on a workpiece support and the workpiece may be operable to provide a surface of the workpiece to the polishing pad assembly. In some embodiments, the polishing pad assembly may be on a platen of an electrochemical mechanical polishing (ECMP) system. The workpiece may include silicon carbide. For example, the workpiece may be a semiconductor workpiece such as a silicon carbide semiconductor workpiece (e.g., wafer).

At 1020, the method 1000 may include providing an electrolyte onto a surface of the polishing pad assembly. For instance, the polishing system may include a delivery system with one or more outlets. The delivery system may deliver a material, such as a slurry, to the polishing pad. The material may include an electrolyte solution such that electrolytes are delivered to polishing pad.

The structure and composition of the polishing pad assembly may allow the electrolyte to disperse throughout the polishing pad. In some examples, the polishing pad may include one or more conductive structures to provide an electrically conductive path through the polishing pad. In some examples, the polishing pad may include one or more voids having an electrolyte solution in the one or more voids. As described herein, the one or more apertures may include one or more holes, apertures, pores, perforations, or gaps between segments of the workpiece, which the electrolyte (e.g., of the slurry) can occupy.

At 1030 the method 1000 may include providing a bias voltage and/or a bias current to the electrolyte through an electrically conductive path for charge carriers in the polishing pad assembly. For instance, the polishing system may include an electrode that is operable to provide a bias voltage or a bias current to the electrolytes of the slurry delivered to the polishing pad assembly. The polishing pad assembly is operable to provide an electrically conductive path for one or more charge carriers (e.g., of the electrolytes) through the polishing pad to a bias source. For example, the electrically conductive path through the polishing pad may include the one or more voids (e.g., pores, apertures, perforations) operable to accommodate the electrolyte in the polishing pad and/or the electrically conductive path may include one or more conductive structures in the polishing pad.

A bias voltage or a bias current may be applied (e.g., via a workpiece electrode) between the wafer and the polishing pad to drive electrochemical reactions to occur at the surface of the workpiece, leading to material dissolution. The slurry applied between the workpiece and the polishing pad facilitates the electrochemical reactions (e.g., oxidation or reduction processes), carries away removed material, and provides lubrication for the mechanical polishing action, as in 1040.

As described herein, the electrically conductive path to the bias source may be implemented in a variety of manners. For example, an electrically conductive support layer may be on the polishing pad and the electrically conductive path may be at least partially through the electrically conductive support layer (e.g., to the bias source). In another example, the polishing pad is on a platen and an adhesive layer is positioned between the polishing pad and the platen. The electrically conductive path is at least partially through the adhesive layer (e.g., to the bias source). In some examples, the electrically conductive path is at least partially through the platen.

The ECMP process facilitated by method 1000 may mitigate the potential edge center effect during polishing of the workpiece. The electrically conductive path provided by the polishing pad thus allows for greater uniformity in the electrochemical reactions occurring at the workpiece surface. In some examples, the ECMP process (e.g., in the case of polishing pads with multiple resistance zones) may be tuned to influence different removal rates at different parts of the workpiece.

For ECMP, while the electrochemical reactions are occurring, mechanical forces may be applied to the workpiece through the polishing pad. At 1040, the method 1000 may include imparting relative motion between the platen and the workpiece. For instance, the platen may be rotated about a first axis causing relative motion between the polishing pad and the workpiece. In some embodiments, the workpiece may be rotated about a second axis imparting relative motion between the polishing pad and the workpiece. In some examples, the second axis may be different from the first axis.

Relative motion between the workpiece and the polishing pad can facilitate the gradual removal of material from the surface of the workpiece. This can occur due to one or more abrasive elements (e.g., abrasive particles), for instance, provided as part of the slurry. In some examples, the polishing pad may include an abrasive containing material, as described herein.

The method 1000 may continue until the ECMP of the surface of the workpiece is complete. Determining when ECMP for a particular workpiece is complete may depend on one or more factors, including the specific requirements of the manufacturing process and the desired outcome for the workpiece surface. For instance, the method 1000 may continue until the desired thickness and uniformity of the workpiece is achieved. Additionally, or alternatively, the method 1000 may continue until a desired level of surface roughness is achieved. The surface roughness may be measured, for example, in terms of surface roughness parameters such as Sa (areal average roughness) or Sz (sum of the largest peak height value and the largest pit depth value). Additionally, or alternatively, the rate at which material (e.g., silicon carbide) is removed during the method 1000 may be monitored. The ECMP may be considered complete once a desired amount of material has been removed or a threshold amount of time has lapsed.

In some examples, visual inspection of the workpiece may provide an indication on the progress of the ECMP provided via method 1000. In some examples, computer vision or optical inspection coupled with machine learning algorithms may provide an indication on the progress of ECMP provided via the method 1000.

In some examples, the completeness of the method 1000 may be based on endpoint detection and/or the monitoring of other process parameters. For example, the polishing system (or operators thereof) implementing method 1000 may be configured to monitor parameters such as electrical current, voltage, or chemical signals to detect changes associated with the removal of material from the workpiece surface. Additionally, or alternatively, the polishing system may monitor temperature, pressure, and electrolyte flow rate to help ensure that ECMP is proceeding as intended. Deviations from the expected process conditions may indicate completion or potential issues with the process.

In an aspect, the present disclosure provides an example polishing system. In some implementations, the example polishing system includes a polishing pad assembly comprising a polishing pad. In some implementations, the example polishing system includes a bias source. In some implementations, the example polishing system includes a workpiece carrier operable to bring the semiconductor workpiece into contact with the polishing pad. In some implementations, the polishing pad assembly is operable to provide an electrically conductive path for one or more charge carriers to the bias source.

In some implementations, the example polishing system further includes a delivery system operable to deliver an electrolyte to the polishing pad, wherein the bias source is electrically coupled to the electrolyte through the electrically conductive path of the polishing pad.

In some implementations of the example polishing system, the bias source is coupled to the polishing pad assembly through a conductive path in the workpiece carrier.

In some implementations, the example polishing system includes an electrically conductive support layer in the polishing pad assembly, wherein the electrically conductive path is coupled to the bias source least partially through the electrically conductive support layer.

In some implementations, the example polishing system includes an adhesive layer, wherein the electrically conductive path is coupled to the bias source at least partially through the adhesive layer.

In some implementations of the example polishing system, the polishing pad assembly is on a platen, wherein the electrically conductive path is coupled to the bias source at least partially through the platen.

In some implementations of the example polishing system, the electrically conductive path of the polishing pad assembly includes one or more voids in the polishing pad, the one or more voids operable to accommodate an electrolyte.

In some implementations of the example polishing system, the one or more voids comprise at least one of: (i) one or more pores; (ii) one or more perforations; (iii) one or more apertures; or (iv) one or more gaps between segments of the polishing pad.

In some implementations of the example polishing system, the electrically conductive path of the polishing pad has a resistivity in a range of about 1 microOhm/cm² to about 500 Ohm/cm² through a thickness of the polishing pad.

In some implementations of the example polishing system, the electrically conductive path of the polishing pad has a resistivity in a range of about 1 microOhm/cm² to about 0.1 Ohm/cm² through a thickness of the polishing pad.

In some implementations of the example polishing system, the electrically conductive path of the polishing pad has a resistivity in a range of about 0.1 Ohm/cm² to about 200 Ohm/cm² through a thickness of the polishing pad.

In some implementations of the example polishing system, the electrically conductive path of the polishing pad has a resistivity in a range of about 0.1 Ohm/cm² to about 500 Ohm/cm² through a thickness of the polishing pad.

In some implementations of the example polishing system, the electrically conductive path of the polishing pad has a sheet resistance in a range of about 6 microOhm·m/m to about 200.0 Ohm·m/m in a radial direction of the polishing pad.

In some implementations of the example polishing system, the electrically conductive path of the polishing pad has a sheet resistance in a range of about 6 microOhm·m/m to about 250 milliOhm·m/m in a radial direction of the polishing pad.

In some implementations of the example polishing system, the electrically conductive path of the polishing pad has a sheet resistance in a range of about 0.25 Ohm·m/m to about 2.0 Ohm·m/m in a radial direction of the polishing pad.

In some implementations of the example polishing system, the electrically conductive path of the polishing pad has a sheet resistance in a range of about 0.25 Ohm·m/m to about 200.0 Ohm·m/m in a radial direction of the polishing pad.

In some implementations of the example polishing system, the electrically conductive path is at least partially in a lateral direction of the polishing pad.

In some implementations of the example polishing system, the polishing pad includes an abrasive containing surface.

In some implementations of the example polishing system, the polishing pad includes one or more electrically conductive structures.

In some implementations of the example polishing system, the workpiece is coupled to the bias source through a conductive path in the workpiece carrier.

In some implementations of the example polishing system, the polishing pad includes a first zone and a second zone.

In some implementations of the example polishing system, the first zone and the second zone are each coupled to a different bias source.

In some implementations of the example polishing system, the first zone has a different sheet resistance or a different resistivity relative to the second zone.

In some implementations of the example polishing system, the polishing system includes an electrochemical mechanical polishing (ECMP) system.

In some implementations of the example polishing system, the semiconductor workpiece includes silicon carbide.

In an aspect, the present disclosure provides an example polishing pad. In some implementations, the example polishing pad includes a composite material. In some implementations, the example polishing pad includes one or more conductive structures to provide an electrically conductive path through the polishing pad.

In some implementations, the example polishing pad includes an electrically conductive support layer.

In some implementations of the example polishing pad, the electrically conductive path is at least partially through the electrically conductive support layer.

In some implementations of the example polishing pad, the electrically conductive path includes one or more voids in the polishing pad.

In some implementations of the example polishing pad, the composite material includes a polymer.

In some implementations of the example polishing pad, the polishing pad includes an abrasive containing surface, the abrasive containing surface includes one or more abrasive elements, the abrasive elements comprising at least one of: (i) diamond; (ii) ceramic; (iii) metal nitride; (iv) metal oxide, (v) metal carbide; (vi) metalloid nitride; (vii) metalloid oxide; (viii) metalloid carbide; (ix) carbon group nitride; (x) carbon group oxide; or (xi) carbon group carbide.

In some implementations of the example polishing pad, the one or more conductive structures comprise a conductive polymer in the composite material.

In some implementations of the example polishing pad, the one or more conductive structures comprise one or more carbon nanotubes.

In some implementations of the example polishing pad, the one or more conductive structures comprise one or more metal structures.

In some implementations of the example polishing pad, the one or more conductive structures comprise one or more voids having an electrolyte solution in the one or more voids.

In some implementations of the example polishing pad, the one or more conductive structures comprise one or more ion conductive structures.

In some implementations of the example polishing pad, the one or more conductive structures comprise one or more solid electrolyte structures.

In an aspect, the present disclosure provides an example method. In some implementations, the example method includes providing the surface of the workpiece on a polishing pad assembly. In some implementations, the example method includes providing an electrolyte onto a surface of the polishing pad assembly. In some implementations, the example method includes providing a bias between the workpiece and the electrolyte through an electrically conductive path at least partially through the polishing pad assembly.

In some implementations, the example method includes imparting relative motion between the polishing pad assembly and the workpiece.

In some implementations of the example method, an electrically conductive support layer is on the polishing pad assembly, wherein the electrically conductive path is at least partially through the electrically conductive support layer.

In some implementations of the example method, the electrically conductive path is at least partially through the platen.

In some implementations of the example method, the electrically conductive path through the polishing pad includes one or more voids in the polishing pad, the one or more voids operable to accommodate the electrolyte.

In some implementations of the example method, the electrically conductive path includes one or more conductive structures in the polishing pad.

In some implementations of the example method, the electrically conductive path of the polishing pad has a resistivity in a range of about 1 microOhm/cm² to about 500 Ohm/cm² through a thickness of the polishing pad.

In some implementations of the example method, the electrically conductive path of the polishing pad has a resistivity in a range of about 1 microOhm/cm² to about 0.1 Ohm/cm² through a thickness of the polishing pad.

In some implementations of the example method, the electrically conductive path of the polishing pad has a resistivity in a range of about 0.1 Ohm/cm² to about 200 Ohm/cm² through a thickness of the polishing pad.

In some implementations of the example method, the electrically conductive path of the polishing pad has a resistivity in a range of about 0.1 Ohm/cm² to about 500 Ohm/cm² through a thickness of the polishing pad.

In some implementations of the example method, the electrically conductive path of the polishing pad has a sheet resistance in a range of about 6 microOhm·m/m to about 200.0 Ohm·m/m in a radial direction of the polishing pad.

In some implementations of the example method, the electrically conductive path of the polishing pad has a sheet resistance in a range of about 6 microOhm·m/m to about 250 milliOhm·m/m in a radial direction of the polishing pad.

In some implementations of the example method, the electrically conductive path of the polishing pad has a sheet resistance in a range of about 0.25 Ohm·m/m to about 2.0 Ohm·m/m in a radial direction of the polishing pad.

In some implementations of the example method, the electrically conductive path of the polishing pad has a sheet resistance in a range of about 0.25 Ohm·m/m to about 200.0 Ohm·m/m in a radial direction of the polishing pad.

In some implementations of the example method, the electrically conductive path is at least partially in a lateral direction of the polishing pad.

In some implementations of the example method, the polishing pad includes an abrasive containing material.

In some implementations of the example method, the workpiece includes silicon carbide.

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. A polishing system for a semiconductor workpiece, comprising:
a polishing pad assembly comprising a polishing pad;
a bias source;
a workpiece carrier operable to bring the semiconductor workpiece into contact with the polishing pad, and
wherein the polishing pad assembly is operable to provide an electrically conductive path for one or more charge carriers to the bias source.

2. The polishing system of claim 1, further comprising a delivery system operable to deliver an electrolyte to the polishing pad, wherein the bias source is electrically coupled to the electrolyte through the electrically conductive path of the polishing pad.

3. The polishing system of claim 2, wherein the bias source is coupled to the polishing pad assembly through a conductive path in the workpiece carrier.

4. The polishing system of claim 1, further comprising:
an electrically conductive support layer in the polishing pad assembly, wherein the electrically conductive path is coupled to the bias source least partially through the electrically conductive support layer.

5. The polishing system of claim 1, further comprising:
an adhesive layer, wherein the electrically conductive path is coupled to the bias source at least partially through the adhesive layer.

6. The polishing system of claim 1, wherein polishing pad assembly is on a platen, wherein the electrically conductive path is coupled to the bias source at least partially through the platen.

7. The polishing system of claim 1, wherein the electrically conductive path of the polishing pad assembly comprises one or more voids in the polishing pad, the one or more voids operable to accommodate an electrolyte.

8. The polishing system of claim 7, wherein the one or more voids comprise at least one of: (i) one or more pores; (ii) one or more perforations; (iii) one or more apertures; or (iv) one or more gaps between segments of the polishing pad.

9. The polishing system of claim 1, wherein the electrically conductive path of the polishing pad has a resistivity in a range of about 1 microOhm/cm² to about 500 Ohm/cm² through a thickness of the polishing pad.

10. The polishing system of claim 1, wherein the electrically conductive path of the polishing pad has a sheet resistance in a range of about 6 microOhm·m/m to about 200.0 Ohm·m/m in a radial direction of the polishing pad.

11. The polishing system of claim 1, wherein the electrically conductive path is at least partially in a lateral direction of the polishing pad.

12. The polishing system of claim 1, wherein the polishing pad comprises an abrasive containing surface.

13. The polishing system of claim 1, wherein the polishing pad comprises one or more electrically conductive structures.

14. The polishing system of claim 1, wherein the workpiece is coupled to the bias source through a conductive path in the workpiece carrier.

15. The polishing system of claim 1, wherein the polishing pad comprises a first zone and a second zone.

16. The polishing system of claim 15, wherein the first zone and the second zone are each coupled to a different bias source.

17. The polishing system of claim 15, wherein the first zone has a different sheet resistance or a different resistivity relative to the second zone.

18. The polishing system of claim 1, wherein the semiconductor workpiece comprises silicon carbide.

19. A polishing pad for a semiconductor workpiece, comprising:
a composite material; and
one or more conductive structures to provide an electrically conductive path through the polishing pad.

20. A method for polishing a surface of a workpiece, the method comprising:
providing the surface of the workpiece on a polishing pad assembly;
providing an electrolyte onto a surface of the polishing pad assembly; and
providing a bias between the workpiece and the electrolyte through an electrically conductive path at least partially through the polishing pad assembly.
